(19) United States
(12) Patent Application Publication
(10) Pub. No.: US 2014/0002982 A1
(43) Pub. Date: Jan. 2, 2014

(54) EXPANSION CARD MODULE AND EXPANSION CARD FIXING STRUCTURE

(71) Applicant: Yong-Liang Zheng, New Taipei City (TW)

(72) Inventor: Yong-Liang Zheng, New Taipei City (TW)

(73) Assignee: WISTRON CORPORATION, New Taipei City (TW)

(21) Appl. No.: 13/565,770

(22) Filed: Aug. 2, 2012

(30) Foreign Application Priority Data
Jun. 27, 2012 (CN) 201210218804.X

(51) Int. Cl. H05K 7/10

(52) U.S. Cl. 361/679.32

(57) ABSTRACT

An expansion card module for a server is provided. The expansion card module includes at least one expansion card fixing structure and at least one expansion card. The expansion card fixing structure includes a bracket, a supporting member, and a handle. The bracket is fixed to the server and includes a first protruding post. The supporting member is slidably disposed on the bracket. The handle is pivotably connected to the supporting member. The expansion card is adapted to be fixed to the supporting member. When the handle is pivoted to push against the first protruding post, the handle and the supporting member slide relative to the bracket so as to drive the expansion card to be plugged into the server.

### CROSS-REFERENCE TO RELATED APPLICATION

This application claims the priority benefit of China application serial no. 201210218804.X, filed Jun. 27, 2012. The entirety of the above-mentioned patent application is hereby incorporated by reference herein and made a part of this specification.

### BACKGROUND OF THE INVENTION

1. Field of the Invention

The present invention relates to an expansion card module and an expansion card fixing structure, and more particularly, to an expansion card module and an expansion card fixing structure suitable for a server.

2. Description of Related Art

Recent years have seen the development of computer servers from traditional tower servers, which are bulky and occupy a lot of space, gradually to rack servers, which include a number 1 U server units installed in a cabinet for unified management, and finally to current blade servers, which have a low profile and low power consumption, occupy less space, and are easy to manage. In response to the increasingly smaller size of the servers while more and more functionalities are demanded, expansion cards are utilized in many servers to save space and expand the server's functionality.

Specifically, connectors on the expansion card are usually plugged into a hard disk back plate of a server. In this fixing manner, the expansion card is suspendedly plugged into the hard disk back plate, which is not securely fixed and can easily become disengaged or be damaged due to shock or unexpected external forces. In addition, a user needs to manually plug/unplug the expansion card which is laborious. Moreover, some expansion cards are designed to have multiple connectors connected to the hard disk back plate at the same time. Therefore, when installing the expansion card, the user often cannot successfully have all the connectors well connected due to warp of the expansion card.

### SUMMARY OF THE INVENTION

Accordingly, the present invention is directed to an expansion card module that includes an expansion card fixing structure capable of securely fixing the expansion card and facilitating the user's plug/unplug operation of the expansion card.

The present invention is also directed to an expansion card fixing structure capable of securely fixing the expansion card and facilitating the user's plug/unplug operation of the expansion card.

The present invention provides an expansion card module adapted for a server. The expansion card module includes at least one expansion card fixing structure and at least one expansion card. The expansion card fixing structure includes a bracket, a supporting member, and a handle. The bracket is fixed to the server and includes a first protruding post. The supporting member is slidably disposed on the bracket. The handle is pivotably connected to the supporting member. The expansion card is adapted to be fixed to the supporting member. When the handle is pivoted to push against the first protruding post, the handle and the supporting member slide relative to the bracket so as to drive the expansion card to be plugged into the server.

The present invention additionally provides an expansion card fixing structure adapted for fixing an expansion card to a server. The expansion card fixing structure includes a bracket, a supporting member, and a handle. The bracket is fixed to the server and includes a first protruding post. The supporting member is slidably disposed on the bracket. The handle is pivotably connected to the supporting member. The expansion card is adapted to be fixed to the supporting member. When the handle is pivoted to push against the first protruding post, the handle and the supporting member slide relative to the bracket so as to drive the expansion card to be plugged into the server.

In one embodiment, the handle has a slide slot, the first protruding post extends into the slide slot, and when the handle is pivoted, the first protruding post moves along the slide slot.

In one embodiment, the handle comprises a protruding portion in the slide slot, and when the protruding portion pushes against the first protruding post as the handle pivots, the handle and the supporting member slide relative to the bracket to drive the expansion card to be plugged into the server.

In one embodiment, the supporting member and the handle are located on two opposite sides of the bracket, respectively, the bracket has a open slot, and the handle is pivotably mounted to the supporting member by means of the open slot.

In one embodiment, the supporting member comprises a pivot axle extending into the open slot and pivotably connected to the handle, and when the handle and the supporting member slide relative to the bracket, the pivot axle moves along the open slot.

In one embodiment, the supporting member comprises a open slot, the bracket comprises a second protruding post extending into the open slot, and when the handle and the supporting member slide relative to the bracket, the second protruding post moves along the open slot.

In one embodiment, the supporting member is slidably mounted to the bracket along a slide direction, and the handle is pivotably mounted to the supporting member about a pivot axis which is perpendicular to the slide direction.

In one embodiment, the expansion card comprises a plurality of first connectors, and the server comprises a plurality of second connectors, and the first connectors are adapted to be connected with the second connectors, respectively, along with the movement of the supporting member relative to the bracket.

In one embodiment, the supporting member comprises at least one hook portion, and the expansion card is adapted to be locked by the hook portion.

In one embodiment, the hook portion comprises a guide inclined surface, and the expansion card is adapted to be locked by the hook portion through the guiding of the guide inclined surface.

In one embodiment, the quantity of the at least one expansion card fixing structure is two, and two opposite ends of the expansion card are adapted to be fixed to the two supporting members, respectively.

In view of the foregoing, the expansion card of the present invention is first fixed to the supporting member and then plugged into the server, such that the expansion card can be more securely fixed, thereby reducing the possibilities of becoming disengaged or damage due to shock or unexpected external force. In addition, the user can plug/unplug the expansion card on the supporting member into/from the server simply by pivoting the handle which causes the handle to push against the first protruding post of the bracket, thereby facilitating the user's plug/unplug operation of the expansion card.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a perspective view of an expansion card module according to one embodiment of the present invention.

FIG. 2 is an exploded view of partial elements of the expansion card module of FIG. 1.

FIG. 3 is a perspective view of an expansion card fixing structure of FIG. 1, viewed from another angle.

FIG. 4 illustrates a pivoting operation of the handle of FIG. 3.

FIG. 5 is a perspective view of the expansion card fixing structure of FIG. 3, viewed from another angle.

### DESCRIPTION OF THE EMBODIMENTS

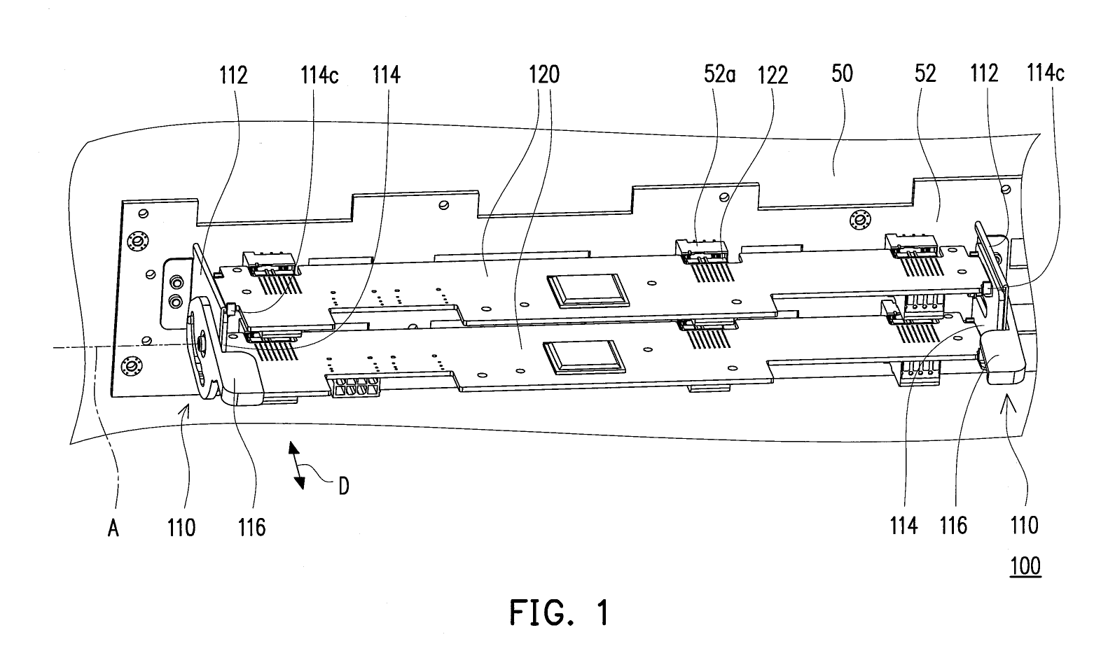

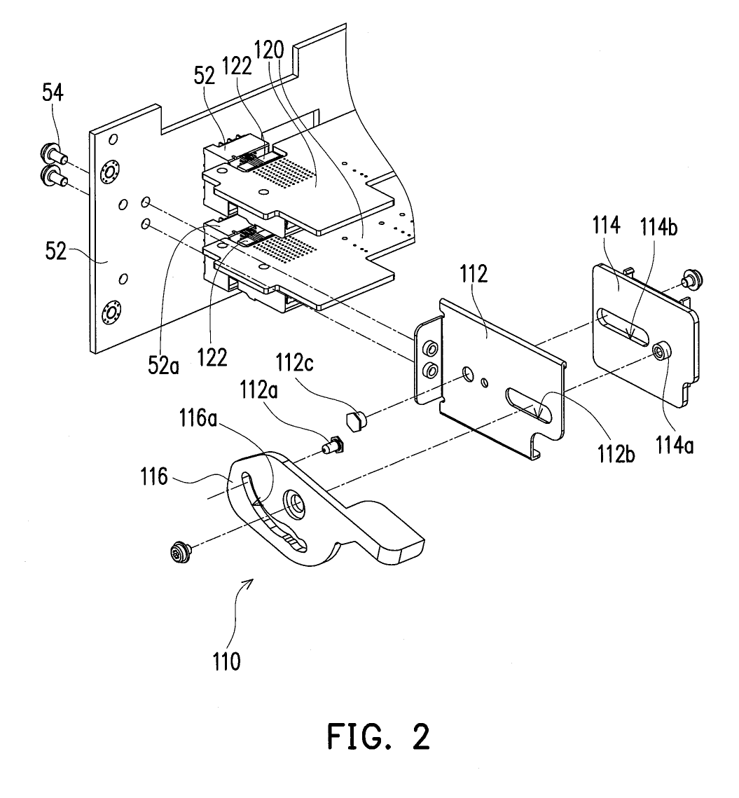

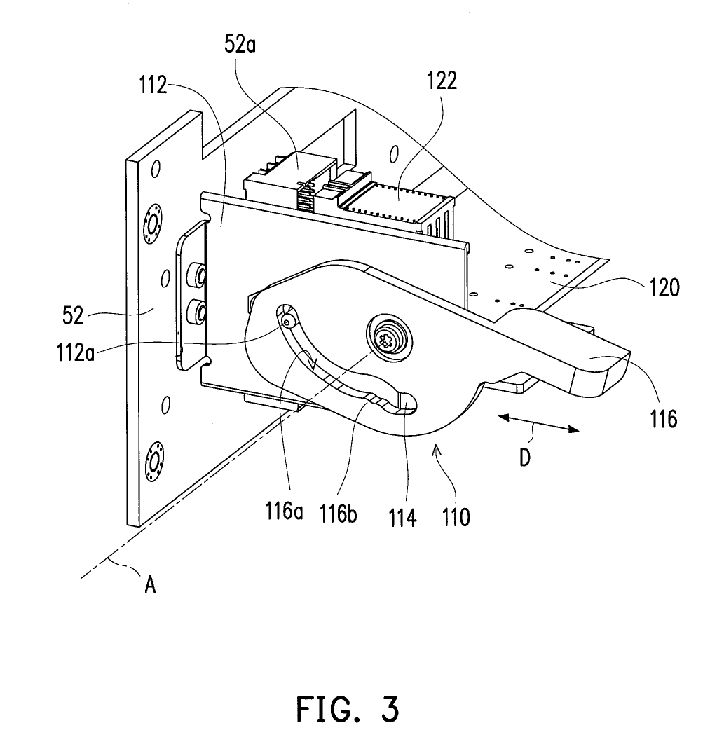

FIG. 1 is a perspective view of an expansion card module according to one embodiment of the present invention. FIG. 2 is an exploded view of partial elements of the expansion card module of FIG. 1. FIG. 3 is a perspective view of an expansion card fixing structure of FIG. 1, viewed from another angle. Referring to FIG. 1 to FIG. 3, the expansion card module 100 of the present embodiment is suitable for a server 50. The expansion card module 100 includes at least one expansion card fixing structure 110 (two fixing structures are illustrated) and at least one expansion card 120 (two expansion cards are illustrated). The expansion card fixing structure 110 includes a bracket 112, a supporting member 114, and a handle 116. The bracket 112 is fixed to a hard disk back plate 52 of a server 50 and includes a first protruding post 112a. The supporting member 114 is slidably mounted to the bracket 112 along a slide direction D. The handle 116 is pivotably mounted to the supporting member 114 about a pivot axis A which is perpendicular to the slide direction D. The handle 116 includes a slide slot 116a and a protruding portion 116b in the slide slot 116a. The first protruding post 112a protrudes into the slide slot 116a. The expansion card 120 is adapted to be fixed to the supporting member 114.

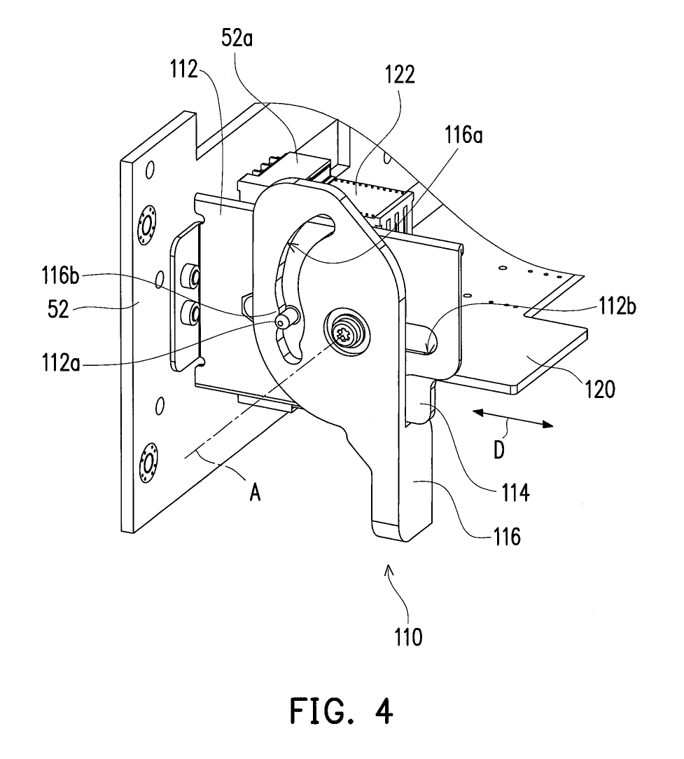

FIG. 4 illustrates a pivoting operation of the handle of FIG. 3. As the handle 116 pivots, the first protruding post 112a of the bracket 112 moves along the slide slot 116b. When the handle 116 pivots to the state illustrated in FIG. 4, the protruding portion 116b of the handle 116 pushes against the first protruding post 112a of the bracket 112 as the handle 116 pivots, and the handle 116 and the supporting member 114 therefore move toward the hard disk back plate 52 of the server 50 along the slide direction D with respect to the bracket 112. At this time, the expansion card 120 fixed to the supporting member 114 is driven to plug into the hard disk back plate 52. When a user desires to unplug the expansion card 120, he or she can pivot the handle 116 from the state illustrated in FIG. 4 to the state illustrated in FIG. 3 so as to move the protruding portion 116b of the handle 116 away from the first protruding post 112a of the bracket 112. At this time, the protruding portion 116b and the first protruding post 112a no longer push against each other, such that the supporting member 114 and the handle 116 can be moved away from the server 50 along the slide direction D, thereby driving the expansion card 120 to disengage from the hard disk back plate 52 of the server 50.

In the construction described above, the expansion card 120 is first fixed to the supporting member 114 and then plugged into the server 50, such that the expansion card 120 can be more securely fixed, reducing the possibility of the expansion card 120 becoming disengaged or damaged due to shock or unexpected external force. In addition, the user can plug/unplug the expansion card 120 on the supporting member 114 into/from the server 50 simply by pivoting the handle 116 which causes the handle 116 to push against the first protruding post 112a of the bracket 112, thereby facilitating the user's plug/unplug operation of the expansion card 120.

In the present embodiment, the material of the supporting member 114 and the handle 116 is, for example, plastic, and the material of the bracket 112 is, for example, metal. The bracket 112 is fastened to the hard disk back plate 52 by fasteners 54 (for example, screws) shown in FIG. 2. In various other embodiments, the material of the supporting member 114 and the handle 116 may be another suitable material, and the material of the bracket 112 may also be another material and may be fixed to the hard disc back plate 52 in another suitable manner. The particular materials and fixing manner described above should not be regarded as limiting.

Referring to FIG. 2, in the present embodiment, the supporting member 114 and the handle 116 are located at two opposite sides of the bracket 112, respectively. The bracket 112 has a open slot 112b. The handle 116 is pivotably mounted to the supporting member 114 by means of the open slot 112b. Specifically, the supporting member 114 includes a pivot axle 114a extending into the open slot 112b and pivotably connected to the handle 116. When the handle 116 and the supporting member 114 slide relative to the bracket 112, the pivot axle 114a of the supporting member 114 moves along the open slot 112b.

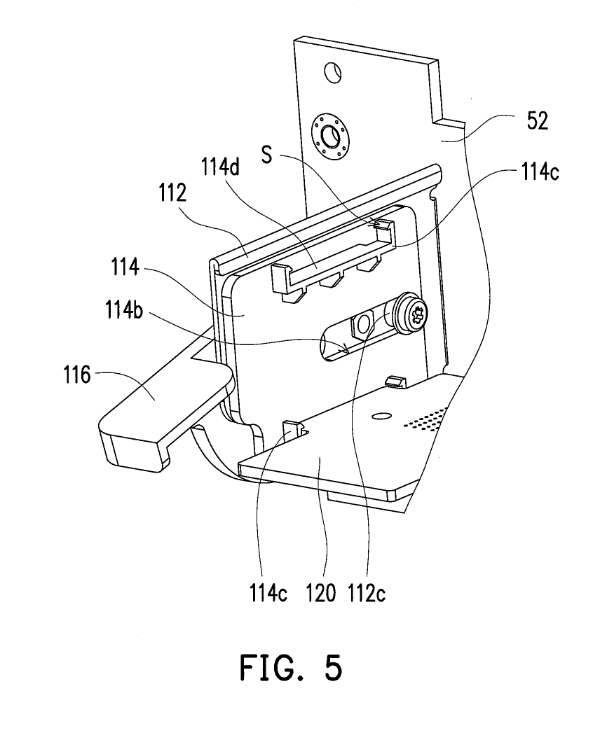

FIG. 5 is a perspective view of the expansion card fixing structure of FIG. 3, viewed from another angle. Referring to FIG. 2 and FIG. 5, the supporting member 114 of the present embodiment has a open slot 114b. The bracket 112 includes a second protruding post 112c extending into the open slot 114b. When the handle 116 and the supporting member 114 slide relative to the bracket 112, the second protruding post 112c moves along the open slot 114b. An extension direction of the open slot 112b of the bracket 112 and an extension direction of the open slot 114b of the supporting member 114 are both parallel to the slide direction D. With the second protruding post 112c of the bracket 112 slidably disposed in the open slot 114b and the pivot axle 114a of the supporting member 114 slidably disposed in the open slot 112b, the supporting member 114 and the bracket 112 can be mounted so as to be stably slidable in the slide direction D relative each other.

As shown in FIG. 1, in the present embodiment, two opposite ends of the expansion card 120 are adapted to be fixed to two supporting members 114, respectively. Referring to FIG. 1 and FIG. 5, specifically, each supporting member 114 of the present embodiment includes at least one hook portion 114c (two hook portions 114c are illustrated) and a supporting portion 114d connected with the hook portion 114c. The expansion card 120 is adapted to be locked by the hook portion 114c and supported on the supporting portion 114d. Each hook portion 114c has a guide inclined surface S, and the expansion card 120 is adapted to be locked by the hook portion 114c through the guiding of the guide inclined surface S.

Referring to FIG. 1, in the present embodiment, each expansion card 120 includes a plurality of first connectors 122, and the hard disk back plate 52 of the server 50 includes a plurality of second connectors 52a. In FIG. 4A and FIG. 4B, only the lower expansion card 120 of FIG. 1 is illustrated while the upper expansion card 120 of FIG. 1 is not illustrated, for the first connectors 122 of the upper expansion card 120 to be clearly seen. When the handle 116 is pivoted from the state shown in FIG. 3 into the state shown in FIG. 4 to drive the supporting member 114 and the expansion card 120 to move along the slide direction D relative to the bracket 112, the first connectors 122 are brought to connect with the second connectors 52, respectively, with the movement of the supporting member 114 and the expansion card 120. The expansion card 120 is first fixed to the supporting member 114, and the first connectors of the expansion card 120 are then connected with the second connectors 52a of the hard disk back plate 52, respectively, with the movement of the supporting member 114, thereby avoiding the situation where the user cannot successfully have all the connectors well connected due to warp of the expansion card 120.

In summary, the expansion card of the present invention is first fixed to the supporting member and then plugged into the server, such that the expansion card can be more securely fixed, thereby reducing the possibility of becoming disengaged or being damaged due to shock or unexpected external force and avoiding the situation where all the connectors cannot be successfully well connected due to warp of the expansion card. In addition, the user can plug/unplug the expansion card on the supporting member into/from the server simply by pivoting the handle which causes the handle to push against the first protruding post of the bracket, thereby facilitating the user's plug/unplug operation of the expansion card.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An expansion card module adapted for a server, the expansion card module comprises:
at least one expansion card fixing structure, comprising:
a bracket fixed to the server and comprising a first protruding post;
a supporting member slidably disposed on the bracket; and
a handle pivotably connected to the supporting member; and
at least one expansion card adapted to be fixed to the supporting member, wherein when the handle is pivoted to push against the first protruding post, the handle and the supporting member slide relative to the bracket so as to drive the expansion card to be plugged into the server.

2. The expansion card module according to claim 1, wherein the handle has a slide slot, the first protruding post extends into the slide slot, and when the handle is pivoted, the first protruding post moves along the slide slot.

3. The expansion card module according to claim 2, wherein the handle comprises a protruding portion in the slide slot, and when the protruding portion pushes against the first protruding post as the handle pivots, the handle and the supporting member slide relative to the bracket to drive the expansion card to be plugged into the server.

4. The expansion card module according to claim 1, wherein the supporting member and the handle are located on two opposite sides of the bracket, respectively, the bracket has a open slot, and the handle is pivotably mounted to the supporting member by means of the open slot.

5. The expansion card module according to claim 4, wherein the supporting member comprises a pivot axle extending into the open slot and pivotably connected to the handle, and when the handle and the supporting member slide relative to the bracket, the pivot axle moves along the open slot.

6. The expansion card module according to claim 1, wherein the supporting member comprises a open slot, the bracket comprises a second protruding post extending into the open slot, and when the handle and the supporting member slide relative to the bracket, the second protruding post moves along the open slot.

7. The expansion card module according to claim 1, wherein the supporting member is slidably mounted to the bracket along a slide direction, and the handle is pivotably mounted to the supporting member about a pivot axis which is perpendicular to the slide direction.

8. The expansion card module according to claim 1, wherein the expansion card comprises a plurality of first connectors, the server comprises a plurality of second connectors, and the first connectors are adapted to be connected with the second connectors, respectively, along with the movement of the supporting member relative to the bracket.

9. The expansion card module according to claim 1, wherein the supporting member comprises at least one hook portion, and the expansion card is adapted to be locked by the hook portion.

10. The expansion card module according to claim 9, wherein the hook portion comprises a guide inclined surface, and the expansion card is adapted to be locked by the hook portion through the guiding of the guide inclined surface.

11. The expansion card module according to claim 1, wherein the quantity of the at least one expansion card fixing structure is two, and two opposite ends of the expansion card are adapted to be fixed to the two supporting members, respectively.

12. An expansion card fixing structure adapted to fix an expansion card to a server, the expansion card fixing structure comprising:
a bracket fixed to the server and comprising a first protruding post;
a supporting member slidably disposed on the bracket, the expansion card being adapted to be fixed to the supporting member; and
a handle pivotably connected to the supporting member, wherein when the handle is pivoted to push against the first protruding post, the handle and the supporting member slide relative to the bracket so as to drive the expansion card to be plugged into the server.

13. The expansion card fixing structure according to claim 12, wherein the handle has a slide slot, the first protruding post extends into the slide slot, and when the handle is pivoted, the first protruding post moves along the slide slot.

14. The expansion card fixing structure according to claim 13, wherein the handle comprises a protruding portion in the slide slot, and when the protruding portion pushes against the first protruding post as the handle pivots, the handle and the supporting member slide relative to the bracket to drive the expansion card to be plugged into the server.

15. The expansion card fixing structure according to claim 12, wherein the supporting member and the handle are located on two opposite sides of the bracket, respectively, the bracket has a open slot, and the handle is pivotably mounted to the supporting member by means of the open slot.

16. The expansion card fixing structure according to claim 15, wherein the supporting member comprises a pivot axle extending into the open slot and pivotably connected to the handle, and when the handle and the supporting member slide relative to the bracket, the pivot axle moves along the open slot.

17. The expansion card fixing structure according to claim 12, wherein the supporting member comprises a open slot, the bracket comprises a second protruding post extending into the open slot, and when the handle and the supporting member slide relative to the bracket, the second protruding post moves along the open slot.

18. The expansion card fixing structure according to claim 12, wherein the supporting member is slidably mounted to the bracket along a slide direction, and the handle is pivotably mounted to the supporting member about a pivot axis which is perpendicular to the slide direction.

19. The expansion card fixing structure according to claim 12, wherein the expansion card comprises a plurality of first connectors, the server comprises a plurality of second connectors, and the first connectors are adapted to be connected with the second connectors, respectively, along with the movement of the supporting member relative to the bracket.

20. The expansion card fixing structure according to claim 12, wherein the supporting member comprises at least one hook portion, and the expansion card is adapted to be locked by the hook portion.

21. The expansion card fixing structure according to claim 20, wherein the hook portion comprises a guide inclined surface, and the expansion card is adapted to be locked by the hook portion through the guiding of the guide inclined surface.
